(19) United States
(12) Patent Application Publication
(10) Pub. No.: US 2007/0095509 A1
(43) Pub. Date: May 3, 2007

(54) Heat dissipation having a heat pipe

(75) Inventors: Hsieh-Kun Lee, Tu-Cheng (TW); Cheng-Tien Lai, Tu-Cheng (TW); Zhi-Bin Tan, Shen-Zhen (CN); Zhi-Yong Zhou, Shen-Zhen (CN); Jiang-Jian Wen, Shen-Zhen (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Foxconn Technology Co., Ltd., Tu-Cheng City (TW)

(21) Appl. No.: 11/265,639

(22) Filed: Nov. 2, 2005

(51) Int. Cl. H05K 7/20

(52) U.S. Cl. 165/104.33; 165/80.3; 361/700

(57) ABSTRACT

A heat dissipation device includes a heat sink (10) and a heat pipe (20). The heat sink includes a base (12), a fins group (16) extending from the base, and a cover (14) contacting with the fins group. The heat pipe surrounds top and bottom and two opposite sides of the fins group and thermally connects with the base and the cover.

### BACKGROUND

1. Field of the Invention

The present invention relates generally to a heat dissipation device, and more particularly to a heat dissipation device using heat pipes for enhancing heat removal from heat-generating components.

2. Related Art

As computer technology continues to advance, electronic components such as central processing units (CPUs) of computers are being made to provide faster operational speeds and greater functional capabilities. When a CPU operates at high speed in a computer enclosure, its temperature can increase greatly. It is desirable to dissipate the heat quickly, for example by using a heat dissipation device attached to the CPU in the enclosure. This allows the CPU and other electronic components in the enclosure to function within their normal operating temperature ranges, thereby assuring the quality of data management, storage and transfer.

A conventional heat dissipation device comprises a heat sink and a heat pipe. The heat sink comprises a base and a plurality of fins extending from the base. The base defines a groove in the top surface thereof, and bottom surface of the base is attached to an electronic component. Each heat pipe has an evaporating portion accommodated in the groove and a condensing portion inserted in the fins. The base absorbs heat produced by the electronic component and transfers the heat directly to the fins through the heat pipe. By the provision of the heat pipe, heat dissipation efficiency of the heat dissipation device is improved.

In order to further improve the heat dissipation efficiency, it is an efficient way to increase the number of the heat pipe such as two or more. However, it will increase the cost of the heat dissipation device using more heat pipes, and the conventional heat dissipation device has low ratio of performance to cost.

### SUMMARY OF THE INVENTION

What is needed is a heat dissipation device with a heat pipe which has a high ratio of performance to cost.

A heat dissipation device in accordance with a preferred embodiment of the present invention comprises a heat sink and a heat pipe. The heat sink comprises a base, a fins group extending from the base, and a cover contacting with the fins group. The heat pipe surrounds the fins group and thermally connects with the base and the cover. The heat pipe has a generally rectangular shape with two juxtaposed free end portions sandwiched between the base and the fins group, a top portion parallel to the free end portions and sandwiched between the cover and the fins group, and two connecting portions interconnecting two ends of the top portion and the free end portions, respectively. The free end portions are constructed as an evaporator for the heat pipe, and the top portion is constructed as a condenser for the heat pipe.

Other objects, advantages and novel features of the invention will become more apparent from the following detailed description when taken in conjunction with the accompanying drawings, in which:

### BRIEF DESCRIPTION OF THE DRAWINGS

FIG. 1 is an assembled view of a heat dissipation device in accordance with a preferred embodiment of the present invention;

FIG. 2 is an exploded view of FIG. 1; and

FIG. 3 is an enlarged view of a heat pipe of FIG. 1.

### DETAILED DESCRIPTION OF THE PREFERRED EMBODIMENT

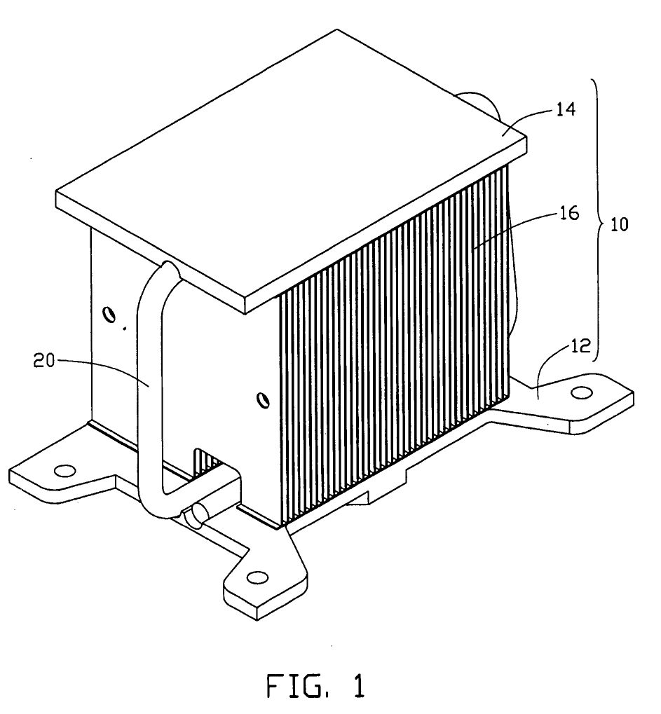

FIG. 1 shows a heat dissipation device in accordance with a preferred embodiment of the present invention. The heat dissipation device comprises a heat sink 10 and a heat pipe 20.

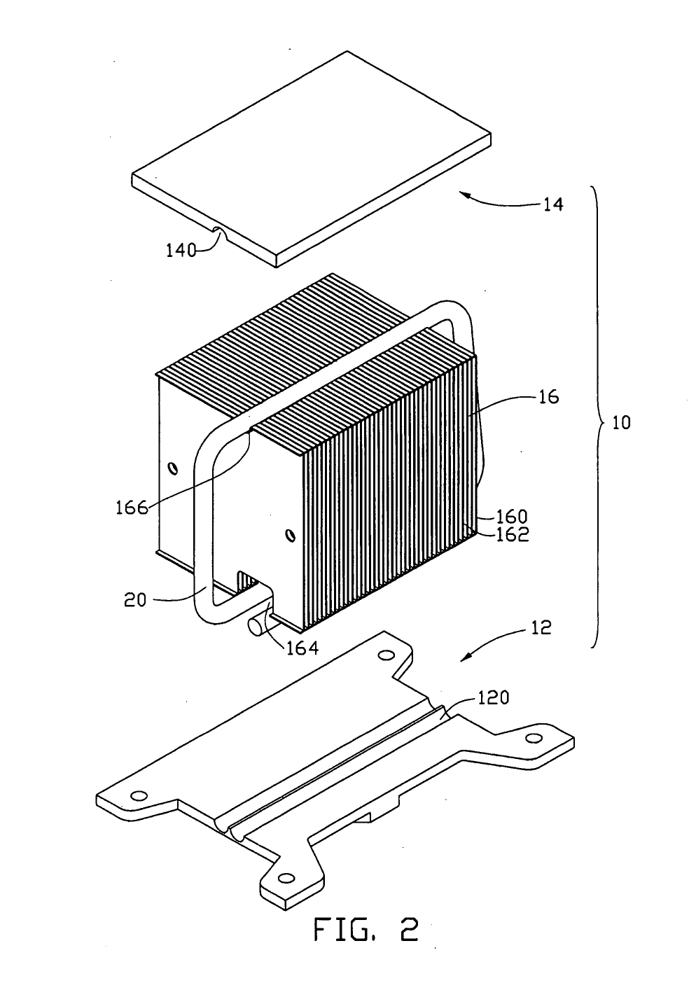

Referring also to FIG. 2, the heat sink 10 comprises a base 12, a cover 14 spaced opposite to the base 12, and a fins group 16 sandwiched between the base 12 and the cover 14. A bottom surface of the base 12 is used for being attached to an electrical component (not shown). The base 12 defines a pair of first grooves 120 in a top surface thereof. The cover 14 defines a second groove 140 in a bottom surface thereof. The fins group 16 comprises a plurality of spaced heat dissipating fins 160. The spaced heat dissipating fins 160 define a plurality of air passageways 162 therebetween. Airflow flows through the air passageways 162 to take heat away from the fins 160. A bottom surface of the fins group 16 defines a first channel 164 corresponding to the first grooves 120. The first channel 164 cooperates with the first grooves 120 to form a first passage. A top surface of the fins group 16 defines a second channel 166 corresponding to the second groove 140. The second channel 166 cooperates with the second groove 140 to form a second passage.

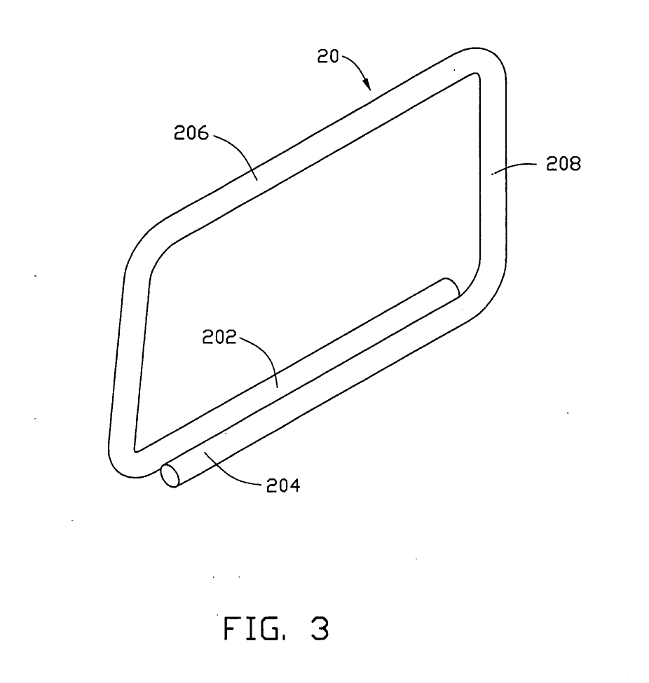

The heat pipe 20 has a rectangular shape and surrounds the top and bottom faces and two sides of the fins group 16. Referring to FIG. 3, the heat pipe 20 comprises two juxtaposed free end portions 202, 204 at a bottom thereof, and a top portion 206 parallel to the free end portions 202, 204. The heat pipe 20 further comprises two connecting portions 208 interconnecting two opposite ends of the top portion 206 and the free end portions 202, 204, respectively. The two connecting portions 208 are perpendicular to the top and free end portions 206, 202, 204 and parallel to each other. In the preferred embodiment, the free end portions 202, 204 are constructed as evaporators of the heat pipe 20 which absorb heat from the electrical component via the 12, and the top portion 206 is constructed as a condenser for the heat pipe 20, which is used for dissipating the heat to the fins 160. Furthermore, in the preferred embodiment, the cover 14 is soldered to the top surface of the fins group 16 and the base 12 is soldered to the bottom surface of the fins group 16. The free end portions 202, 204 of the rectangle-shaped heat pipe 20 are soldered in the first passage defined by the first grooves 120 and the first channel 164 so that the free end portions 202, 204 are thermally connected with the base 12 and the fins group 16. The top portion 206 of the rectangle-shaped heat pipe 20 is soldered in the second passage defined by the second groove 140 and the second channel 166 so that the top portion 206 is thermally connected with the cover 14 and the fins group 16. The connecting portions 208 are disposed at the opposite sides of the fins group 16.

In operation of the heat dissipation device of the preferred embodiment, the base 12 absorbs the heat from the electronic component and a major part of the heat is directly transferred to the free end portions 202, 204 of the heat pipe 20. The free end portions 202, 204 are evaporating portions of the heat pipe 20. A minor part of the heat is conducted upwardly to the fins 160 via a soldering connection between the fins 160 and the base 12. The major part of the heat received by the heat pipe 20 causes liquid in the free end portions 202, 204 thereof to evaporate into vapor. The vapor flows upwardly along the two connecting portions 208 simultaneously. Then the vapor is condensed into liquid in the top portion 206 (which is a condensing portion of the heat pipe 20). The condensed liquid returns to the free end portions 202, 204 along wick structures in the heat pipe 20. Thus, the major part of the heat is transferred to the cover 14 and the fins 160 to be dissipated into surrounding environment.

In the preferred embodiment, the heat pipe 20 comprises two connecting portions 208 disposed at opposite sides of the fins group 16 and connecting the free end portions 202, 204 and the top portion 206. The heat pipe 20 can thereby transfer the heat from the base 12 to the cover 14 along the two connecting portions 208 simultaneously, whereby the heat dissipation efficiency of the heat pipe 20 is the same as using two U-shaped heat pipes. Furthermore, the cost of two U-shaped heat pipes is much more than that of the one heat pipe 20. Therefore, the heat dissipation device of the present invention has a better ratio regarding performance to cost. In an alternative embodiment, the cover can be used to contact with the electronic component. For this, the top portion 206 is constructed as an evaporator and the free end portions 202, 204 are constructed as condensers for the heat pipe 20.

It is understood that the invention may be embodied in other forms without departing from the spirit thereof. Thus, the present examples and embodiments are to be considered in all respects as illustrative and not restrictive, and the invention is not to be limited to the details given herein.

We claim:

1. A heat dissipation device comprising:
a heat sink comprising a base, a fins group extending from the base, and a cover contacting with the fins group; and
a continuous heat pipe entirely surrounding a perimeter of the fins group and thermally connecting with the base and the cover.

2. The heat dissipation device as claimed in claim 1, wherein the heat pipe comprises a pair of free end portions thermally engaging with the base and a middle portion thermally engaging with the cover.

3. The heat dissipation device as claimed in claim 2, wherein the heat pipe further comprises a pair of connecting portions extending from opposite ends of the middle portion and connecting with the free end portions respectively.

4. The heat dissipation device as claimed in claim 2, wherein the free end portions are juxtaposed and received between the base and a bottom of the fins group, and the middle portion of the heat pipe is received between the cover and a top of the fins group.

5. The heat dissipation device as claimed in claim 4, wherein said base defines a pair of first grooves, the fins group defining a first channel corresponding to the first grooves to form a first passage to receive the free end portions of the heat pipe.

6. The heat dissipation device as claimed in claim 4, wherein the cover defines a second groove, the fins group defining a second channel corresponding to the second groove to form a second passage to receive the middle portion of the heat pipe.

7. The heat dissipation device as claimed in claim 2, wherein the free end portions and middle portion of the heat pipe are parallel to each other.

8. The heat dissipation device as claimed in claim 1, wherein the heat pipe is rectangle-shaped.

9. A heat dissipation device comprising:
a base;
a cover parallel to the base;
a fin member sandwiched between the base and the cover; and
a heat pipe having a first portion thermally connecting with the base, a second portion thermally connecting with the cover, and two connecting portions disposed between the base and the cover and at opposite sides of the fin member and connecting the first portion and second portion of the heat pipe.

10. The heat dissipation device as claimed in claim 9, wherein the first portion consists of two free end portions of the heat pipe and the second portion is parallel to the first portion.

11. The heat dissipation device as claimed in claim 10, wherein the base comprises a pair of first grooves respectively accommodating the free end portions of the first portion of the heat pipe.

12. The heat dissipation device as claimed in claim 10, wherein the cover comprises a second groove accommodating the second portion of the heat pipe.

13. A heat dissipation device for a heat-generating electronic component comprising:
a fins group having a bottom for thermally contacting with the heat-generating electronic component; and
a heat pipe having two free end portions functioning as an evaporator of the heat pipe and received in the bottom of the fins group and a condenser between the free end portions and thermally contacting an upper portion of the fins group.

14. The heat dissipation device of claim 13, wherein the condenser is parallel to the free end portions.

15. The heat dissipation device of claim 14 further comprising a top wall soldered to a top of the fins group, wherein the condenser of the heat pipe is located between the top wall and the top of the fins group.

16. The heat dissipation of claim 14 further comprising a base wall soldered to the bottom of the fins group, wherein the free end portions are located between the base wall and the bottom of the fins group.

17. The heat dissipation of claim 14, wherein the heat pipe is substantially rectangle-shaped, and has two connecting portion interconnecting two ends of the condenser and the free end portions, respectively.
